(19) United States
(12) Patent Application Publication
(10) Pub. No.: US 2014/0365150 A1
(43) Pub. Date: Dec. 11, 2014

(54) METHOD AND DEVICE FOR DETERMINING A CHARGE STATE OF AN ELECTRIC ENERGY STORE

(71) Applicant: SIEMENS AKTIENGESELLSCHAFT, 80333 MÜNCHEN (DE)

(72) Inventors: Alexander Hahn, Rottenbach (DE); Jacob Johan Rabbers, Baiersdorf (DE); Wolfgang Weydanz, Buckenhof (DE); Holger Wolfschmidt, Erlangen (DE)

(73) Assignee: SIEMENS AKTIENGESELLSCHAFT, 80333 MÜNCHEN (DE)

(21) Appl. No.: 14/370,816

(22) PCT Filed: Dec. 21, 2012
(86) PCT No.: PCT/EP2012/076574

§ 371 Date: Jul. 7, 2014

(30) Foreign Application Priority Data
Jan. 12, 2012 (DE) 10 2012 200 414.9

(51) Int. Cl. G01R 31/36

(52) U.S. Cl. CPC G01R 31/3648; G01R 31/362; G01R 31/3665
USPC 702/63

(57) ABSTRACT

A method for determining a charge state of an electric energy store, having the following steps: measuring a voltage of the electric energy store on the basis of a charge quantity which is removed from or supplied to the electric energy store as a voltage characteristic curve and ascertaining a virtual open-circuit voltage characteristic curve from the measured voltage using at least one operating parameter of the electric energy store, ascertaining a first derivative and/or a second derivative of the virtual open-circuit voltage characteristic curve according to the charge quantity removed from or supplied to the electric energy store, detecting at least one characteristic of the first derivative and/or the second derivative of the virtual open-circuit voltage characteristic curve, and determining the charge state of the electric energy store using the detected at least one characteristic, is provided.

### CROSS-REFERENCE TO RELATED APPLICATIONS

This application claims priority to PCT Application No. PCT/EP2012/076574, having a filing date of Dec. 21, 2012, based off of DE Application No. 102012200414.9, having a filing date of Jan. 12, 2012, the entire contents of which are hereby incorporated by reference.

### FIELD OF TECHNOLOGY

The following relates to a method and a device for determining a state of charge of an electrical energy store.

### BACKGROUND

DE 38 53 86 4 T2 describes a charging device for charging rechargeable batteries, comprising a means for supplying electrical charging energy to a rechargeable battery to quickly charge the rechargeable battery, comprising a means for capturing a voltage of the rechargeable battery, comprising a means for providing a preselected reference voltage and comprising a means for comparing the voltage of the battery with the preselected reference voltage.

FIG. 6 shows an exemplary illustration of a graph with a discharge curve of a lithium-ion rechargeable battery with oxide cathode, that is to say, a cathode with LiCoO₂, LiNiO₂, LiMn₂O₄ or Li—NMC or other related materials.

A discharge curve ELK of the lithium-ion rechargeable battery with oxide cathode is illustrated in the graph shown in FIG. 6. The X axis shows the discharge capacity of the lithium-ion rechargeable battery in ampere-hours, Ah for short; the Y axis shows the no-load voltage of the lithium-ion rechargeable battery with oxide cathode in volts, V for short.

The discharge curve ELK is typical for lithium-ion rechargeable batteries with oxide cathode: a weak but almost constant drop of the voltage during discharging of the lithium-ion rechargeable battery until a cell voltage of approximately 3.8 V, then a steep drop in the cell voltage until the end of discharging of the lithium-ion rechargeable battery.

In lithium rechargeable battery systems with oxide cathodes, there is, in general, a correlation between the state of charge and the no-load voltage. This can be derived from the characteristic behavior of the cathode and anode potentials and allows conclusions to be drawn about the state of charge. In addition, this relationship is unambiguous since charge and discharge have the same curve profile.

By measuring comparison curves, a precise, that is to say having only approximately 5% error, determination of the state of charge, SOC for short, of the lithium-ion rechargeable battery can thus be achieved by no-load voltage measurements.

The discharge curve ELK shown in FIG. 6 for a system with oxide cathode has a constantly positive or negative gradient. As shown, a voltage value can always be correlated to the charge drawn from the rechargeable battery, and vice versa.

Almost all modern methods of determining the state of charge are based, above all, on a charge measurement, such as a Coulomb counter, for example, an integration over time of the charging current drawn or supplied.

Depending on the respective type of the electrochemical energy store, such as lead cells, nickel-based systems or lithium-ion systems, for example, various methods for state identification and for determining the state of charge of the electrochemical energy store are used. Said methods are, for example, no-load voltage measurements, acid density measurements or concentration measurements of the electrolyte and measurements of the charge flow-rate.

However, owing to temporal and/or load-related aging, the total capacity of the rechargeable battery changes. Likewise, energy is lost from the battery over time owing to self-discharge. It is therefore periodically necessary to calibrate to a new total capacity, which calibration, under certain conditions, requires a full cycle in order to determine the total capacity of the rechargeable battery once again and thus to calibrate the charge count as determination of the state of charge.

During use of rechargeable batteries in “float operation”, that is to say without fully completed charge and discharge cycles or without a regular charge and/or discharge of the rechargeable batteries, said calibration point is not reached in some cases for a relatively long time. Likewise, in the case of an expensive, highly precise current measurement, the measurement of the no-load voltage and hence the correlation of the no-load voltage to the state of charge physically quickly reaches the limits of measuring electronics or the electrochemistry predefined by the cell chemistry.

In addition, U.S. Pat. No. 7,405,571 B1 and U.S. Pat. No. 760,568 A, U.S. Pat. No. 6,563,318 B2, U.S. Pat. No. 6,661,231 B1, U.S. Pat. No. 6,832,171 B2, U.S. Pat. No. 7,062,390 B2, U.S. Pat. No. 7,190,171 B2 and US 2006/0125482 A1 should be cited as prior art.

### SUMMARY

An aspect relates to a means of identifying the state of charge of electrical energy stores in order to enable the state of charge of the electrical energy store to be determined.

Accordingly, embodiments of the invention provides a method for determining a state of charge of an electrical energy store, having the steps of: measuring a voltage of the electrical energy store on the basis of an amount of charge drawn from or supplied to the electrical energy store as a voltage characteristic curve and calculating a virtual no-load voltage characteristic curve from the measured voltage, taking into account at least one operating parameter of the electrical energy store, calculating a first derivative and/or a second derivative of the virtual no-load voltage characteristic curve according to the amount of charge drawn from or supplied to the electrical energy store, capturing at least one characteristic of the first derivative and/or of the second derivative of the virtual no-load voltage characteristic curve and determining the state of charge of the electrical energy store on the basis of the captured at least one characteristic.

According to another embodiment of the invention, a device for determining a state of charge of an electrical energy store, having a sensor device for measuring an amount of charge drawn from or supplied to the electrical energy store and for measuring, as a voltage characteristic curve, a voltage of the electrical energy store as a function of the amount of charge drawn from or supplied to the electrical energy store, a storage unit with stored voltage characteristic curve data and a control device for calculating a virtual no-load voltage characteristic curve from the measured voltage, taking into account at least one operating parameter of the electrical energy store, for calculating a first derivative and/or a second derivative of the virtual no-load voltage characteristic curve according to the amount of charge drawn from or supplied to the electrical energy store, for capturing at least one characteristic of the first derivative and/or of the second derivative of the virtual no-load voltage characteristic curve and for determining the state of charge of the electrical energy store on the basis of the captured at least one characteristic.

Embodiments of the invention include analyzing the curve profile of the virtual no-load voltage characteristic curve in respect of the gradient and/or the curvature. The gradient or the curvature can be determined by simple measurement of at least two or at least three consecutive state-of-charge values and voltage values. The change in the state of charge is calculated by integration of a measured current and charge. The voltage of the electrical energy store is either measured at an instant with no current flow or the voltage is calculated with inclusion of the amount of charge which is presently drawn or supplied and of the current in the calculation. For this purpose, a virtual no-load voltage is calculated from the voltage values by means of a stored current or voltage characteristic and in correlation with the temperature of the electrical energy store and/or the current loading of the electrical energy store and/or the internal resistance of the electrical energy store and/or the hysteresis of the voltage which occurs. “Hysteresis of the voltage of the store” is intended to mean that the store has a different no-load voltage depending on the preceding mode of operation, that is to say specifically whether said store was previously charged or discharged.

The obtained state-of-charge values and voltage values are compared either with measured-value tables or with limit values. Thus, regulation and/or disconnection criteria for charge regulation of the electrical energy store emerge therefrom. Furthermore, regulation can be derived from reaching a certain value of gradient and/or curvature.

The reliable determination of the state of charge and hence the prompt identification and subsequent avoidance of an exhaustive discharge or overcharging of the electrical energy store have important advantages with respect to the safety and durability of cells with relatively flat voltage characteristic curves, for instance lithium-metal-phosphate cells, in particular lithium-iron-phosphate cells, lithium-manganese-phosphate cells, lithium-cobalt-phosphate cells or lithium titanate cells.

Precise determination of the state of charge is likewise fundamental for the control of applications. On the basis of the change in the gradient and/or the curvature of the voltage characteristic curve of the electrical energy store, regulation for a power reduction or for charging and discharging the electrical energy store can be derived. The state of charge of the electrical energy store can easily be determined in the edge regions from gradient and/or curvature from the profile of the voltage of the electrical energy store plotted against the amount of charge drawn or supplied.

The comparison with data stored as voltage characteristic curve data in the storage unit is used for balancing; a possibility of regulating the charging and discharging processes results herefrom in order also to ensure operation of the electrical energy store with reduced power.

For this purpose, a value for the second derivative of the voltage is defined, for example, which value can be assumed only in the stated limit regions close to the end of the charging or discharging and unambiguously indicates that the charging or discharging is soon to be finished.

A harsh finish to the charging or discharging in the event of charging or discharging the electrical energy store can thus be avoided in advance. The reliability is therefore increased in two important points. Firstly, the occurrence of operating voltages which are outside of an operating range of the electrical energy store and lead to damage to the cell can be captured in good time and avoided. Secondly, an increased durability is achieved in the operating mode by conservation of the electrical energy store, so-called lower cycle depth.

In the case of one possible embodiment of the method according to the invention, a temperature of the electrical energy store and/or a current loading of the electrical energy store and/or an internal resistance of the electrical energy store and/or a hysteresis of the voltage of the electrical energy store is calculated as the at least one operating parameter of the electrical energy store. In this way, a current loading can comprise a current direction and a current value.

In the case of one embodiment of the method according to the invention, the voltage is measured by a sensor device and the amount of charge drawn from or supplied to the electrical energy store is captured by the sensor device during the measurement. The temperature, the current loading, the internal resistance and the hysteresis of the voltage of the electrical energy store have some influence on the calculation of the virtual no-load voltage from the measured voltage.

In the case of one embodiment of the method according to the invention, a profile of the no-load voltage of the electrical energy store against the amount of charge drawn from or supplied to the electrical energy store is captured or calculated with the virtual no-load voltage characteristic curve.

In the case of one possible embodiment of the method according to the invention, the state of charge of the electrical energy store is determined on the basis of a comparison of the captured or virtual no-load voltage of at least one characteristic of the virtual no-load voltage characteristic curve with voltage characteristic curve data stored in a storage unit.

In the case of one alternative embodiment of the method according to the invention, a zero-point region of the first derivative is used as the at least one characteristic of the first derivative.

In the case of one embodiment of the method according to the invention, a zero-point region and/or a region of the second derivative having a change of mathematical sign is used as the at least one characteristic of the second derivative. In the case of one possible embodiment of the method according to the invention, a peak value or a predefined limit value of the first derivative and/or of the second derivative of the virtual no-load voltage characteristic curve is used as the at least one characteristic of the first derivative and/or of the second derivative of the virtual no-load voltage characteristic curve.

In the case of one possible embodiment of the method according to the invention, the state of charge of the electrical energy store is determined on the basis of a curvature and/or on the basis of a gradient of the virtual no-load voltage characteristic curve.

In the case of one possible embodiment of the method according to the invention, the curvature and/or the gradient of the virtual no-load voltage characteristic curve is determined in an edge region of the virtual no-load voltage characteristic curve.

In the case of one possible embodiment of the method according to the invention, a disconnection limit of a minimum or maximum voltage of the electrical energy store is prevented from being reached by determining of the state of charge of the electrical energy store.

In the case of one possible embodiment of the method according to the invention, a lithium-ion battery with a two-phase material or with another material which has a flat discharge characteristic curve as active material is used as the electrical energy store.

In the case of one possible embodiment of the method according to the invention, a lithium-ion battery with lithium-iron-phosphate or with lithium-manganese-phosphate or with lithium-cobalt-phosphate or with another lithium-metal-phosphate as cathode material is used as the electrical energy store.

In the case of one possible embodiment of the method according to the invention, a lithium-ion battery with lithium titanate as active material is used as the electrical energy store.

In the case of one possible embodiment of the method according to the invention, the amount of charge drawn from or supplied to the electrical energy store is calculated in steps of 1% of a maximum state of charge of the electrical energy store, preferably in steps of 0.2% of the maximum state of charge and particularly preferably in steps of less than 0.1% of the maximum state of charge.

In the case of one possible embodiment of the device according to the invention, the sensor device is configured to calculate, with the voltage characteristic curve, a profile of the no-load voltage of the electrical energy store against the amount of charge drawn from or supplied to the electrical energy store.

In the case of one possible embodiment of the device according to the invention, the control device is configured to determine the state of charge of the electrical energy store on the basis of a comparison of the calculated at least one characteristic of the virtual no-load voltage characteristic curve with voltage characteristic curve data stored in a storage unit.

In the case of one possible embodiment of the device according to the invention, a temperature of the electrical energy store and/or a current loading of the electrical energy store and/or an internal resistance of the electrical energy store and/or a hysteresis of the voltage of the electrical energy store is provided as the at least one operating parameter of the electrical energy store.

The described configurations and developments can be combined with one another as desired, insofar as this is expedient.

Further possible configurations, developments and implementations of the invention also include combinations of features of the invention which have been described previously or are described below in respect of the exemplary embodiments, which combinations are not explicitly mentioned.

### BRIEF DESCRIPTION

Some of the embodiments will be described in detail, with reference to the following figures, wherein like designations denote like members, wherein:

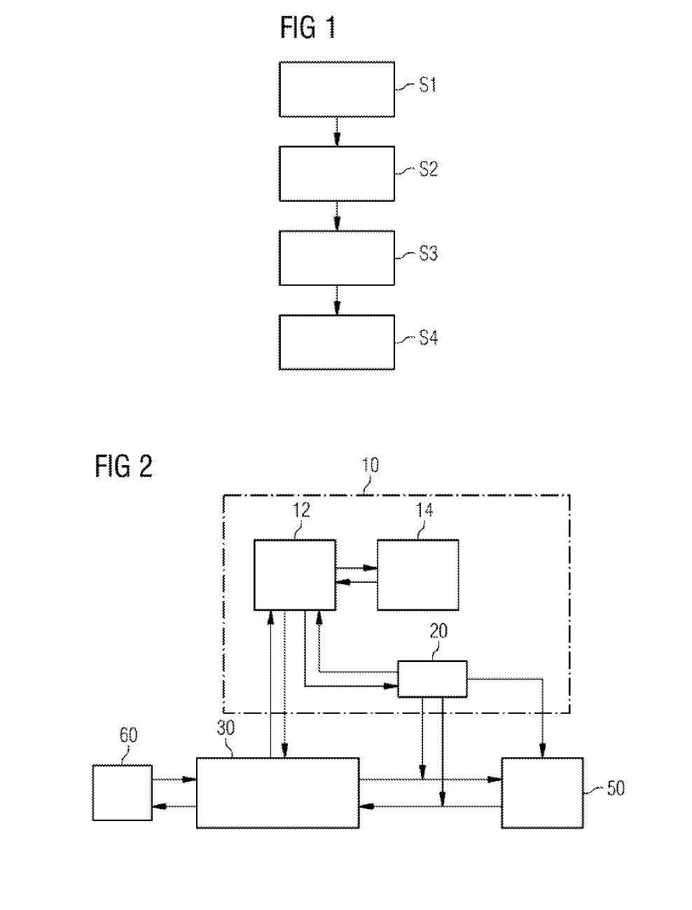

FIG. 1 shows an illustration of a flow chart of a possible embodiment of the method;

FIG. 2 shows an illustration of an embodiment of a device;

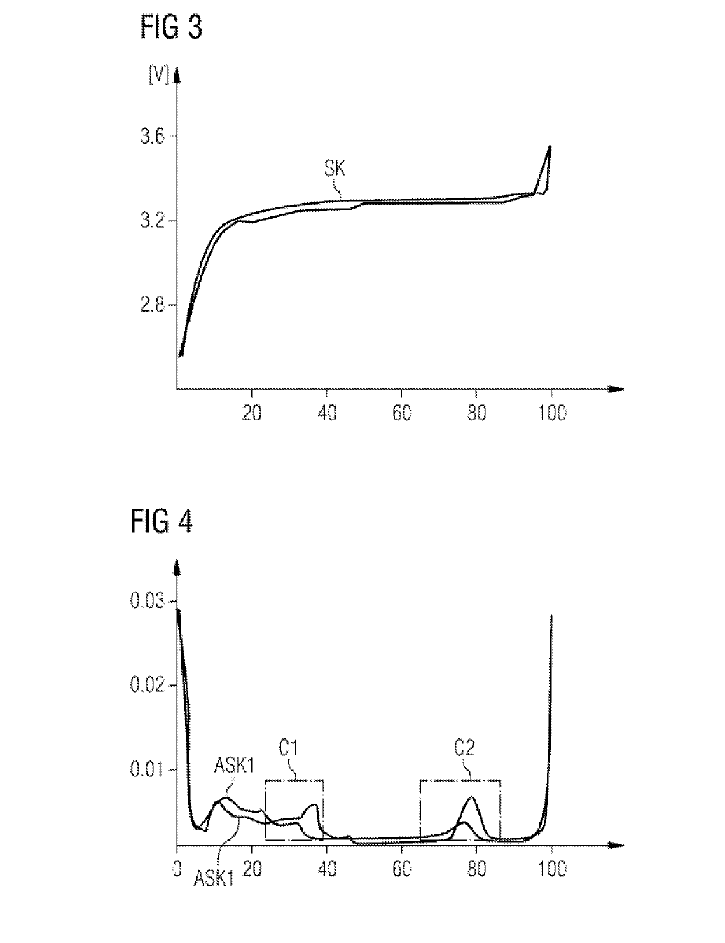

FIG. 3 shows an illustration of a graph with a voltage characteristic curve of an electrical energy store according to a possible embodiment;

FIG. 4 shows an illustration of a graph with a first derivative of a virtual no-load voltage characteristic curve of an electrical energy store;

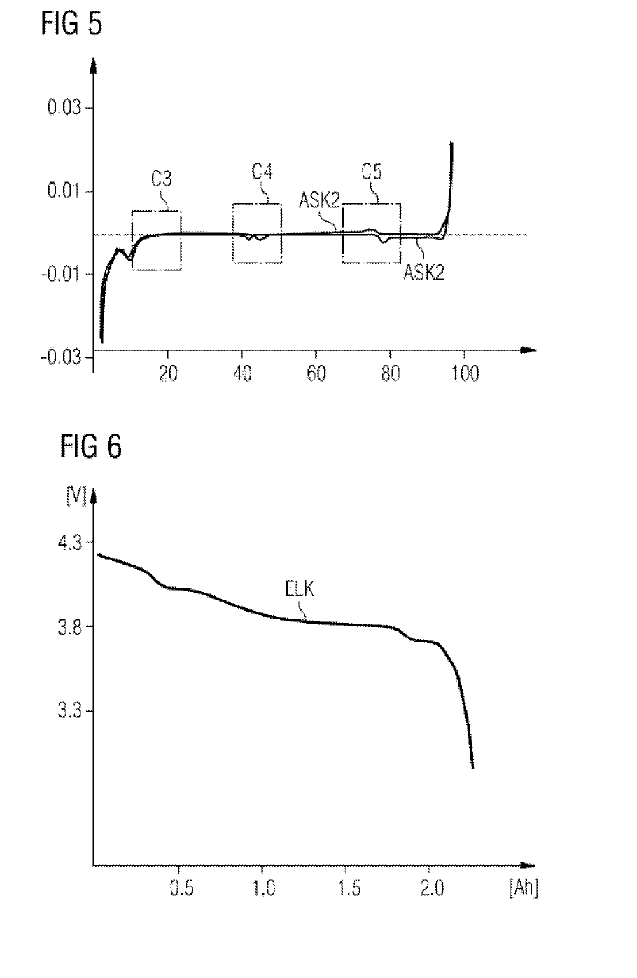

FIG. 5 shows an illustration of a graph with a second derivative of a virtual no-load voltage characteristic curve of an electrical energy store; and

FIG. 6 shows an exemplary illustration of a graph with a discharge curve of a lithium-ion rechargeable battery with oxide cathode.

### DETAILED DESCRIPTION

FIG. 1 shows an illustration of a flow chart of a possible embodiment of the method according to the invention.

In a first step of the method, a voltage of the electrical energy store 50 is measured S1, as a voltage characteristic curve SK, as a function of an amount of charge drawn from or supplied to the electrical energy store 50 and a virtual no-load voltage characteristic curve is calculated from the measured voltage, taking into account at least one operating parameter of the electrical energy store 50.

In a second step S2 of the method, a first derivative ASK1 and/or a second derivative ASK2 of the virtual no-load voltage characteristic curve according to the amount of charge drawn from or supplied to the electrical energy store 50 is calculated S2.

By way of example, the hysteresis behavior of the electrical energy store 50 is taken into account in the case of calculating the virtual no-load voltage characteristic curve. The virtual no-load voltage obtained therefrom forms the basis for the further calculations.

In a third step of the method, at least one characteristic C1-C5 of the first derivative ASK1 and/or the second derivative ASK2 of the virtual no-load voltage characteristic curve is captured S3.

In a fourth step S4 of the method, the state of charge of the electrical energy store 50 is determined S4 on the basis of the captured at least one characteristic C1-C5.

FIG. 2 shows an illustration of a device according to a possible embodiment of the present invention.

A device 10 for determining a state of charge of an electrical energy store 50 comprises a control device 12, a storage unit 14 and a sensor device 20. The sensor device 20 is configured, for example, to measure an amount of charge drawn from or supplied to the electrical energy store 50 and to measure a voltage of the electrical energy store 50 on the basis of the amount of charge drawn from or supplied to the electrical energy store 50. The sensor device 20 is designed, for example, as an electrical current integrator and/or as an electrical voltage measuring device.

The no-load voltage plotted against the amount of charge drawn or supplied in this case represents, for example, a voltage characteristic curve SK of the electrical energy store 50.

The storage unit 14 has, for example, stored voltage characteristic curve data. By way of example, the storage unit 14 is designed as a flash storage device with digital storage chips and ensures non-volatile storage with low power usage at the same time.

The control device 12 is configured, for example, to calculate a first derivative ASK1 and/or a second derivative ASK2 of the virtual no-load voltage characteristic curve according to the amount of charge drawn from or supplied to the electrical energy store 50. The control device 12 is designed as a programmable logic controller, for example.

Furthermore, the control device 12 is provided to capture at least one characteristic C1-C5 of the first derivative ASK1 and/or the second derivative ASK2 of the virtual no-load voltage characteristic curve and to determine S5 the state of charge of the electrical energy store 50 on the basis of the captured at least one characteristic C1-C5 of the virtual no-load voltage characteristic curve.

A charging or a discharging process of the electrical energy store 50 is controlled, for example, via a charging regulator 30 which is coupled to an electrical consumer 60.

By way of example, the electrical consumer 60 is designed as an electrical on-board power supply system of a motor vehicle, which electrical on-board power supply system is to be supplied by the electrical energy store 50.

FIG. 3 shows an illustration of a graph with a voltage characteristic curve SK of a lithium-iron-phosphate rechargeable battery of an electrical energy store according to a possible embodiment of the present invention.

The abscissa axis indicates the state of charge of the electrical energy store 50; the ordinate axis illustrates the no-load voltage of the electrical energy store 50 in volts.

A lithium-iron-phosphate rechargeable battery is a further development of the lithium-ion rechargeable battery. LiFePO₄, for example, is used as cathode material. Lithium rechargeable batteries having LiFePO₄ cathodes have two marked differences in comparison with lithium rechargeable batteries with oxide cathodes.

Firstly, the voltage characteristic curve SK plotted against the state of charge shows no marked gradient, or even none at all, at least in partial regions, as a result of which a direct correlation between voltage and state of charge is complicated.

Secondly, a hysteresis forms in the case of the equilibrium potential curve. This is caused by various voltage levels which are dependent on the past history, that is to say on a previous charging or previous discharging of the electrical energy store. FIG. 3 shows a typical equilibrium voltage profile of a lithium-iron-phosphate cell used as electrical energy store.

The total voltage drop of the voltage between a state of charge of 10% and a state of charge of 90% of the electrical energy store 50 is only approximately 150 mV. Furthermore, there are partial regions of the voltage characteristic curve SK, for instance in a state-of-charge region of between 60% and 90%, in which partial regions there is hardly any voltage change in the voltage of the electrical energy store 50 for electrochemical reasons.

The hysteresis of the voltage characteristic curve SK is likewise a problem, which often results in two no-load voltage values for one state-of-charge value. It is therefore not possible to unambiguously assign a no-load voltage to a state of charge of the electrical energy store 50.

A clear increase in the gradient for a state of charge of less than 15% and for a state of charge of the electrical energy store 50 of more than 95% can already been seen from the curve profile of the voltage characteristic curve SK of the electrical energy store 50 in FIG. 3.

This is partly to be attributed to the significantly increasing internal resistance in this region of a cell with a lithium-iron-phosphate cathode. Said limit regions are to be avoided during normal operation for reasons of increased aging. Similarly, the disconnection limits of the storage system are close to being reached here, which requires restricted use of the store.

A precise and continuous determination of the gradient of the voltage characteristic curve SK from FIG. 3 leads to the gradient values of the first derivative ASK1 being plotted against the charge drawn from or supplied to the electrical energy store 50, as is done in FIG. 4.

FIG. 4 shows an illustration of a graph with a first derivative of a virtual no-load voltage characteristic curve of an electrical energy store according to a possible embodiment of the present invention.

The X axis represents the state of charge of the electrical energy store 50; the Y axis shows the value of the first derivative.

Two first derivatives ASK1 are depicted on the graph. Although the gradient is almost zero in the central region in a state-of-charge region of from 40% to 60%, a significant increase in the gradient can be seen at the edge. A gradient of almost zero clearly indicates the restricted correlation between voltage and state of charge. However, the rise in the edge regions can thus be used as possible regulation parameter for the limit regions of a lithium-iron-phosphate cell.

The state of charge can be determined for the edge regions by means of the magnitude of the gradient. By way of example, characteristics C1, C2 are used for this, which can be designed as significant peak values or zero points.

FIG. 5 shows an illustration of a graph with a second derivative of a virtual no-load voltage characteristic curve of an electrical energy store according to a possible embodiment of the present invention.

The X axis shows the state of charge of the electrical energy store 50; the Y axis shows the value of the second derivative.

It is clear from the second derivatives ASK2 illustrated in FIG. 5 that the curvature of the no-load voltage characteristic curve is negative for low states of charge of the electrical energy store 50 and is positive for high states of charge of the electrical energy store 50.

As common data set of gradient and curvature, a two-part item of information emerges, which item of information allows a voltage to be unambiguously assigned to a state of charge in the edge regions of the no-load voltage characteristic curve.

The value of the curvature of the no-load voltage characteristic curve can be used as additional regulation and control parameter for the electrical energy store 50.

In accordance with the behavior of the first derivatives ASK1 in FIG. 4, significant peak values appear in the second derivatives ASK2 illustrated in FIG. 5 at a state of charge of the electrical energy store 50 of 40% and 80%, which peak values are designated as characteristics C4 and C5.

Another characteristic C3 of the second derivative ASK2 of the no-load voltage characteristic curve for a state-of-charge value of the electrical energy store 50 of under 20% is also illustrated. Said characteristics C3-C5 of the second derivative ASK2 can be used for additional information and conclusions for charge regulation of the electrical energy store 50.

Alternative embodiments—which are not shown—of the method and the device are also possible, in which embodiments characteristics of a third or higher derivative of the no-load voltage characteristic curve and/or characteristics of the no-load voltage characteristic curve itself are used for determining the state of charge of the electrical energy store 50.

The method according to the invention is implemented by means of software which can be integrated in a charge regulator for an electrical energy store.

1. A method for determining a state of charge of an electrical energy store, comprising:
measuring, as a voltage characteristic curve, a voltage of the electrical energy store as a function of an amount of charge drawn from or supplied to the electrical energy store and calculating a virtual no-load voltage characteristic curve from the measured voltage, taking into account at least one operating parameter of the electrical energy store;
calculating a first derivative and/or a second derivative of the virtual no-load voltage characteristic curve according to the amount of charge drawn from or supplied to the electrical energy store;
capturing at least one characteristic of the first derivative and/or of the second derivative of the virtual no-load voltage characteristic curve; and
determining the state of charge of the electrical energy store on a basis of the captured at least one characteristic.

2. The method as claimed in claim 1, wherein a temperature of the electrical energy store and/or a current loading of the electrical energy store and/or an internal resistance of the electrical energy store and/or a hysteresis of the voltage of the electrical energy store is calculated as the at least one operating parameter of the electrical energy store.

3. The method as claimed in claim 1, wherein the voltage is measured by a sensor device and the amount of charge drawn from or supplied to the electrical energy store is captured by the sensor device during the measurement.

4. The method as claimed in claim 1, wherein a profile of the virtual no-load voltage of the electrical energy store against the amount of charge drawn from or supplied to the electrical energy store is captured with the virtual no-load voltage characteristic curve.

5. The method as claimed in claim 1, wherein the state of charge of the electrical energy store is determined on a basis of a comparison of the captured at least one characteristic of the virtual no-load voltage characteristic curve with voltage characteristic curves stored in a storage unit.

6. The method as claimed in claim 1, wherein a zero-point region of the first derivative is used as the at least one characteristic of the first derivative.

7. The method as claimed in claim 1, wherein a zero-point region and/or a region of the second derivative having a change of mathematical sign is used as the at least one characteristic of the second derivative.

8. The method as claimed in claim 1, wherein a peak value or a predetermined limit value of the first derivative and/or of the second derivative of the virtual no-load voltage characteristic curve is used as the at least one characteristic of the first derivative and/or of the second derivative of the virtual no-load voltage characteristic curve.

9. The method as claimed in claim 1, wherein the state of charge of the electrical energy store is determined on the basis of a curvature and/or on a basis of a gradient of the virtual no-load voltage characteristic curve.

10. The method as claimed in claim 9, wherein the curvature and/or the gradient of the virtual no-load voltage characteristic curve is determined in a predefinable edge region of the virtual no-load voltage characteristic curve.

11. The method as claimed in claim 1, wherein a disconnection limit of a minimum or maximum voltage of the electrical energy store is prevented from being reached by determining the state of charge of the electrical energy store.

12. The method as claimed in claim 1, wherein a lithium-ion battery with a two-phase material or with another material which has a flat discharge characteristic curve as active material is used as the electrical energy store.

13. The method as claimed in claim 1, wherein a lithium-ion battery with lithium-iron-phosphate or with lithium-manganese-phosphate or with lithium-cobalt-phosphate or with another lithium-metal-phosphate as cathode material is used as the electrical energy store.

14. The method as claimed in claim 1, wherein a lithium-ion battery with lithium titanate as active material is used as the electrical energy store.

15. The method as claimed in claim 1, wherein the amount of charge drawn from or supplied to the electrical energy store is calculated in steps of 0.1%-1% of a maximum state of charge of the electrical energy store.

16. A computer program for performing the method for determining a state of charge of an electrical energy store as claimed in claim 1.

17. A device for determining a state of charge of an electrical energy store, comprising:
a sensor device for measuring an amount of charge drawn from or supplied to the electrical energy store and for measuring, as a voltage characteristic curve, a voltage of the electrical energy store as a function of the amount of charge drawn from or supplied to the electrical energy store;
a storage unit with stored voltage characteristic curve data; and
a control device for calculating a virtual no-load voltage characteristic curve from the measured voltage, taking into account at least one operating parameter of the electrical energy store, for calculating a first derivative and/or a second derivative of the virtual no-load voltage characteristic curve according to the amount of charge drawn from or supplied to the electrical energy store, for capturing at least one characteristic of the first derivative and/or of the second derivative of the virtual no-load voltage characteristic curve and for determining the state of charge of the electrical energy store on the basis of the captured at least one characteristic.

18. The device as claimed in claim 17, wherein the sensor device is configured to capture, with the voltage characteristic curve, a profile of the voltage of the electrical energy store against the amount of charge drawn from or supplied to the electrical energy store.

19. The device as claimed in claim 17, wherein the control device is configured to determine the state of charge of the electrical energy store on a basis of a comparison of the captured at least one characteristic with voltage characteristic curve data stored in a storage unit.

20. The device as claimed in claim 17, wherein a temperature of the electrical energy store and/or a current loading of the electrical energy store and/or an internal resistance of the electrical energy store and/or a hysteresis of the voltage of the electrical energy store is provided as the at least one operating parameter of the electrical energy store.
